(19) United States
(12) Patent Application Publication
(10) Pub. No.: US 2007/0241364 A1
(43) Pub. Date: Oct. 18, 2007

(54) SUBSTRATE WITH TRANSPARENT CONDUCTIVE FILM AND PATTERNING METHOD THEREFOR

(75) Inventors: Yasuhiko Akao, Yonezawa-shi (JP); Shotaro Hanada, Amagasaki-shi (JP); Tateo Baba, Amagasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: ASAHI GLASS CO., LTD., Tokyo (JP)

(21) Appl. No.: 11/766,150

(22) Filed: Jun. 21, 2007

Related U.S. Application Data
(63) Continuation of application No. PCT/JP05/23546, filed on Dec. 16, 2005.

(30) Foreign Application Priority Data
Dec. 21, 2004 (JP) 2004-369294

(51) Int. Cl. H01L 33/00

(52) U.S. Cl. 257/103

(57) ABSTRACT

A substrate with transparent conductive film which is suitable for laser patterning and can be produced with high productivity, is provided. A substrate with transparent conductive film, which comprises a glass substrate and a transparent conductive film composed mainly of indium oxide, formed thereon, wherein the average domain diameter at the surface of the transparent conductive film is at most 150 nm. Such transparent conductive film is formed by sputtering at a substrate temperature of at most 250° C. during the film deposition.

### TECHNICAL FIELD

The present invention relates to a substrate with transparent conductive film useful for a flat panel display (FPD).

### BACKGROUND ART

A transparent conductive film composed mainly of indium oxide to be used mainly for transparent electrodes for FPD, has heretofore been patterned by a wet etching method by photolithography (e.g. Patent Document 1). However, as the substrate has been getting larger in size, patterning by a wet etching method has had a problem of increased costs, because of the difficulty in preparation of a large-size mask to be used for the lithography, or because of an increase in the number of process steps. Therefore, a laser patterning method is now being employed whereby a pattern is formed directly on the substrate by a laser. In the laser patterning method, patterning is carried out by evaporating the transparent conductive film by a laser. However, it is rather difficult to evaporate a tin-doped indium oxide (ITO) film as one of transparent conductive films composed mainly of indium oxide which have been heretofore employed, and it is necessary to scan slowly with a high laser output in order to carry out the evaporation, whereby there has been a problem that the productivity is low.

Patent Document 1: JP-A-7-64112

### DISCLOSURE OF THE INVENTION

It is an object of the present invention to provide a substrate with transparent conductive film which is suitable for laser patterning and can be produced with high productivity and a flat panel display employing it, and a patterning method for such a substrate with transparent conductive film.

### MEANS TO ACCOMPLISH THE OBJECT

The present invention provides a substrate with transparent conductive film, which comprises a glass substrate and a transparent conductive film composed mainly of indium oxide, formed thereon, wherein the average domain diameter at the surface of the transparent conductive film is at most 150 nm.

The present invention further provides the above substrate with transparent conductive film, wherein the transparent conductive film is amorphous; the above substrate with transparent conductive film, wherein the transparent conductive film is used for laser patterning; the above substrate with transparent conductive film, wherein the transparent conductive film is formed by sputtering at a substrate temperature of at most 250° C. during the film deposition; and a substrate with patterned transparent conductive film obtained by subjecting the above substrate with transparent conductive film to laser patterning, followed by heat treatment at a temperature of at least 300° C.

Further, the present invention provides a patterning method for a substrate for transparent conductive film, which comprises patterning the above substrate with transparent conductive film by means of a laser.

### EFFECTS OF THE INVENTION

By using the substrate with transparent conductive film of the present invention, it becomes possible to carry out patterning with high precision with a low laser output, thus providing excellent productivity. The transparent conductive film of the present invention can be patterned with a low laser output, whereby it is possible to carry out the patterning without presenting no substantial damage to the glass substrate, thus providing excellent productivity and product quality.

Further, it is possible to carry out the patterning effectively with a low laser output, whereby the scanning speed can be increased with the same laser output, and thus the productivity can be increased. Further, by carrying out heat treatment after the patterning, it becomes possible to form a patterned transparent conductive film having electrical conductivity and transparency suitable for FPD.

### BRIEF DESCRIPTION OF THE DRAWINGS

FIG. 1 is a SEM image of the surface of a conventional ITO film.

FIG. 2 is a SEM image of the surface of the ITO film in Example 1.

FIG. 3 is a SEM image of the surface of the ITO film in Example 2.

FIG. 4 is a cross-sectional view of the substrate with transparent conductive film of the present invention.

### BEST MODE FOR CARRYING OUT THE INVENTION

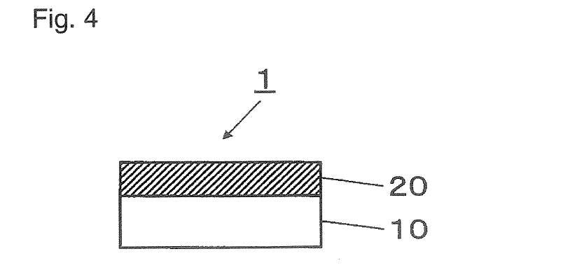

The substrate 1 with transparent conductive film of the present invention has a structure as shown in FIG. 4 wherein a transparent conductive film 20 composed mainly of indium oxide is formed on a glass substrate 10.

The glass substrate to be used in the present invention is not particularly limited, and may, for example, be soda lime glass, high strain point glass or alkali-free glass. However, it is preferably alkali-free glass whereby the characteristics as FPD can be maintained.

The thickness of the glass substrate is preferably from 0.4 to 5 mm from the viewpoint of transparency and durability. The average surface roughness Rₐ of the glass substrate is preferably from 0.1 to 10 nm, more preferably from 0.1 to 5 nm, particularly preferably from 0.1 to 1 nm. Further, the luminous transmittance (as measured by JIS Z8722 (1994)) of the glass substrate is preferably at least 80%, from the viewpoint of the transparency.

The transparent conductive film composed mainly of indium oxide is preferably such that the content of indium oxide in the transparent conductive film is at least 80 mass%. Specifically, from the viewpoint of the transparency and electrical conductivity, an ITO (indium-doped tin oxide) film or an IZO (zinc-doped indium oxide) film may, for example, be mentioned. Particularly preferred is an ITO film from the viewpoint of the chemical stability. Further, the film thickness of the transparent conductive film is preferably from 50 to 500 nm, particularly from 100 to 300 nm, from the viewpoint of the electrical conductivity and transparency.

The luminous transmittance (as measured by JIS Z8722 (1994)) of the transparent conductive film composed mainly of indium oxide, is preferably at least 70%, particularly preferably at least 80%, since the transparency can be maintained when it is used for transparent electrodes. Further, the specific resistance of the transparent conductive film composed mainly of indium oxide is preferably at most 0.001 Ωcm, particularly preferably at most 0.0005 Ωcm, since the resistance value as a transparent electrode can be maintained.

On the substrate side of the above transparent conductive film, an undercoating film may be formed for the purpose of e.g. improving the flatness. The material for the undercoating film may, for example, be silica, zirconia or titania. Even when such an undercoating film is formed, the transparent conductive film of the present invention can be easily processed by laser patterning, such being preferred.

The above transparent conductive film is characterized in that the average domain diameter at the surface of the transparent conductive film is at most 150 nm, particularly at most 100 nm. Here, at most 150 nm includes a case where the domain is so small that it cannot be observed. Here, the domain means a region where a number of the minimum elements (hereinafter referred to as grains) constituting the film are aggregated, which can be ascertained when the film surface is observed by e.g. a scanning electron microscopic image.

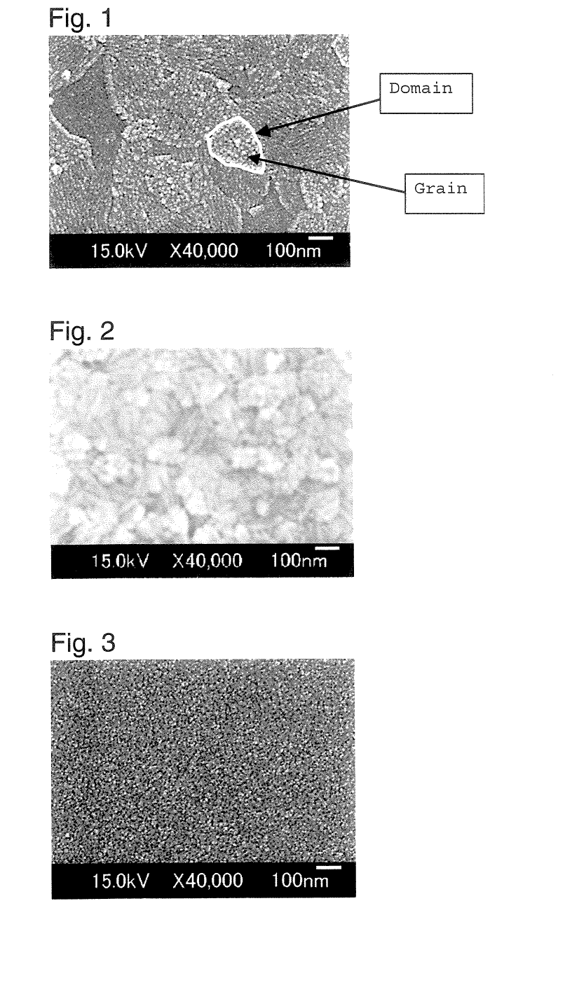

FIGS. 1 to 3 are SEM images when the surfaces of ITO films formed under different conditions were observed by a scanning electron microscope. The forming conditions will be described hereinafter. In FIG. 1, a number of fine grains are aggregated to form a domain, and such domains are formed in a stepped fashion. Here, the average domain diameter can be obtained in such a manner that optional ten domains shown in a SEM image are taken, and the average values of the longest diameters and the shortest diameters are respectively calculated, and the average domain diameter is obtained as an average value of the ten domains. The average domain diameter in FIG. 1 is 185 nm. Although theoretically not well understood, such a conductive film requires a high laser output for the patterning.

However, in FIGS. 2 and 3, the domains are finer. In FIG. 2, the average domain diameter is at most 100 nm, and in FIG. 3, no domain is observed. Although theoretically not well understood, such a conductive film can be patterned sufficiently with a low laser output, as it is considered to have weak portions in the interatomic bonds, so that it can be easily evaporated. Particularly preferred is a film in which domains are so small that they cannot be observed, whereby laser patterning can be carried out with a low output.

The above transparent conductive film is preferably amorphous. When the transparent conductive film is amorphous, patterning can be carried out with a low laser output, such being preferred from the viewpoint of the productivity.

With respect to the laser patterning conditions, the wavelength of the laser is preferably from 350 to 1,070 nm, as a high output laser transmitter within such a wavelength region is available. Further, the laser beam diameter is preferably from 5 to 200 μm, with a view to forming highly fine patterns. Further, the energy for laser irradiation is preferably from 0.5 to 1 mW from the viewpoint of the pattern-forming rate. The irradiation time is preferably from 1 to 10 seconds from the viewpoint of the pattern-forming rate. Specifically, as the laser, it is possible to preferably use a fundamental wave (1,064 nm) or a second harmonic wave (532 nm) of a YAG laser. Particularly, the transparent conductive film of the present invention can be processed by laser patterning with a laser output of at most 10 W, such being preferred. Usually, ITO films require a laser energy of at least 1 mJ for laser patterning. Whereas, by using an ITO film of the present invention, laser patterning can be carried out with a laser energy of at least 0.2 mJ and less than 1 mJ. Further, by making the ITO film to be amorphous, laser patterning can be carried out with a still lower laser energy at a level of at most 0.7 mJ. It is preferred that laser patterning can be carried out with such a low energy of from 0.2 to 0.7 mJ, whereby patterning can be carried out with excellent productivity without damaging the glass substrate.

Further, if the laser energy is larger than a certain level, the glass substrate is likely to be damaged. Accordingly, the laser energy is preferably less than 1 mJ.

The method for producing the transparent conductive film is not particularly limited, but a sputtering method is preferred from the viewpoint of the productivity or the uniformity in the performance for e.g. the film thickness. In a case where the transparent conductive film is an ITO film, such an ITO film can be formed by using ITO as a target material. Further, when a sputtering method is employed, the substrate temperature during the film deposition is preferably from 20 to 250° C., further preferably from 20 to 200° C., and a substrate temperature of from 20 to 100° C., is particularly preferred, since an amorphous film can thereby be formed. When an amorphous film is to be used for FPD, it tends to be opaque and inadequate in electrical conductivity in many cases. However, the transparency and electrical conductivity can be restored by simple treatment such as heating after the patterning, such being preferred. The heating is preferably from 300 to 600° C. and is preferably carried out in an oxygen atmosphere, particularly in atmospheric air. Even if the transparent conductive film of the present invention is an amorphous film as mentioned above, it can be preferably used for FPD by subjecting it to such heat treatment.

The transparent conductive film of the present invention is suitably used as transparent electrodes for FPD. FPD may, for example, be a plasma display panel (PDP), a liquid crystal display device (LCD), an electroluminescence display (ELD) or a field emission display (FED).

The transparent conductive film of the present invention can easily be processed by laser patterning to provide excellent productivity, whereby it is useful for FPD such as a plasma display.

### EXAMPLES

Now, Examples will be described, but it should be understood that the present invention is by no means restricted thereto.

### Example 1

As a glass substrate, a high strain point glass for PDP (PD200, manufactured by Asahi Glass Company, Limited, thickness: 2.8 mm, luminous transmittance: 90%) was used. On the glass substrate, an ITO film was formed by sputtering by using an ITO target containing 10 mass % of tin oxide, based on the entire target. The substrate temperature during the film deposition was 200° C. As a sputtering gas, argon gas was mainly used, and a very small amount of oxygen gas was added to bring the specific resistance to be minimum. The composition of the film was equal to the target.

The film thickness, luminous transmittance, specific resistance, crystal structure and average domain diameter of the transparent conductive film, and the evaporation energy ratio of the ITO film by a laser are shown in Table 1. Further, the SEM image of the surface of the formed transparent conductive film is shown in FIG. 2. The evaluation methods are as follows.

(1) Film Thickness of the Transparent Conductive Film

Measured by a stylus profilometer DEKTAK-3030 (manufactured by SLOAN).

(2) Luminous Transmittance

Measured by the method of JIS Z8772 (1994) using an apparatus called a luminous transmittance measuring meter (MODEL 305, manufactured by Asahi Spectra Co., Ltd.).

(3) Specific Resistance

The sheet resistance was measured by a four-probe method by using LORESTA IP device (manufactured by Mitsubishi Chemical Corporation), and the specific resistance was calculated by a product of the sheet resistance and the film thickness. Further, “E-4” in Table 1 means 10⁻⁴.

(4) Crystal Structure of the Film

Using the X-ray diffraction pattern (X-ray diffraction apparatus Ultima III, manufactured by Rigaku Corporation) of an ITO film, an ITO film showing no diffraction peak was regarded as amorphous.

(5) Average Domain Diameter

The determination was carried out by a SEM image of a scanning electromicroscope. Optional ten domains shown in the SEM image were taken out, and the average values of the longest diameters and the shortest diameters were respectively calculated, whereupon the average domain diameter was calculated as an average value of the ten domains.

(6) Evaporation Energy Ratio by a Laser

Using a PDP laser repair device (LRV-1612, manufactured by SEIWA OPTICAL Co., Ltd.) laser irradiation was repeated until the ITO film was no longer evaporated under such conditions that the laser wavelength was 532 nm, the laser beam diameter was 90 μm, the energy for irradiation once was 0.2 mW, and the irradiation time was 1 sec, and the cumulating energy was taken as the evaporation energy required for evaporation of the ITO film. Here, the evaporation energy was obtained by averaging energies at different five points of the same ITO film.

The evaporation energy in Example 1 was 0.2×3.5 (the average in the number of irradiations at five points)=0.7 mJ. Here, the evaporation energy ratio is a value evaluated on such a basis that the evaporation energy in Example 3 is taken as 1, and as mentioned hereinafter, the evaporation energy in Example 3 is 1 mJ, and the evaporation energy ratio=0.7 mJ/1 mJ=0.7.

Here, “disappear by evaporation” means that the film at the site irradiated with the laser, becomes no longer visually observed, and the same applies in other Examples.

### Example 2

An ITO film was formed in the same manner as in Example 1 except that in Example 1, the substrate temperature during the film deposition was changed to 100° C., and the film thickness of the ITO film was changed to 130 nm. The film was evaluated in the same manner as in Example 1, and the results are shown in Table 1. Further, the SEM image of the surface of the formed transparent conductive film is shown in FIG. 3.

Then, laser patterning was carried out in the same manner as in Example 1 except that the number of irradiation times with a laser was changed to once. The evaporation energy in Example 2 was 0.2 mJ×1 (average in the number of irradiation times at five points)=0.2 mJ. Further, the evaporation energy ratio=0.2 mJ/1 mJ=0.2.

### Example 3 (Comparative Example)

An ITO film was formed in the same manner as in Example 1 except that in Example 1, the substrate temperature during the film deposition was changed to 300° C., and the film thickness of the ITO film was changed to 130 nm. The film was evaluated in the same manner as in Example 1, and the results are shown in Table 1. Further, the SEM image of the surface of the formed transparent conductive film is shown in FIG. 1.

Then, laser patterning was carried out in the same manner as in Example 1 except that the number of irradiation times with a laser was changed to five times. The evaporation energy in Example 3 was 0.2×5 (average of the number of irradiation times at five points)=1 mJ. In each of Examples 1 to 3, no damage to the glass substrate by the laser was found, or if found, the damage was so slight that it did not influence over the performance.

As is evident from Table 1, the ITO film in Example 1 formed at the substrate temperature of at most 200° C. had small domains (average domain diameter: 100 nm), and the ITO film was evaporated with an output at an evaporation energy ratio of 0.7 as compared with Example 3. Especially, the amorphous film having no domain in Example 2 was easy to evaporate, and the ITO film was evaporated with an output at an evaporation energy ratio of 0.2 as compared with Example 3, such being preferred for laser patterning.

The transparent conductive film of the present invention has a specific resistance slightly larger than the conventional one, but by subjecting it to heat treatment at a temperature of at least 300° C. after the laser patterning, the specific resistance decreases, and it is possible to obtain a specific resistance and transparency close to a usual ITO film. Further, in a case where heat treatment of the transparent conductive film of the present invention is required, it is preferred to provide a heat treating step separately, but it is also possible to utilize a subsequent heat treating step such as a step for baking the dielectric.

TABLE 1

| | Unit | Ex. 1 | Ex. 2 | Ex. 3 |
|---|---|---|---|---|
| Substrate | ° C. | 200 | 100 | 300 |
| temperature | | | | |
| during film | | | | |
| deposition | | | | |
| Film | nm | 200 | 130 | 130 |
| thickness | | | | |
| Luminous | % | 79 | 83 | 86 |
| transmittance | | | | |
| Specific | Ω | 2.50 × E−4 | 8.19 × E−4 | 1.95 × E−4 |
| resistance | | | | |
| Structure of | | Crystalline | Amorphous | Crystalline |
| film | | | | |
| Average | nm | 100 | No domain | 185 |
| domain | | | | |
| diameter | | | | |
| Evaporation | | 0.7 | 0.2 | 1 |
| energy ratio | | | | |

### INDUSTRIAL APPLICABILITY

The substrate with transparent conductive film of the present invention can be processed easily by laser patterning and is useful particularly as a substrate for FPD.

The entire disclosure of Japanese Patent Application No. 2004-369294 filed on Dec. 21, 2004 including specification, claims, drawings and summary is incorporated herein by reference in its entirety.

What is claimed is:

1. A substrate with transparent conductive film, which comprises a glass substrate and a transparent conductive film composed mainly of indium oxide, formed thereon,
wherein the average domain diameter at the surface of the transparent conductive film is at most 150 nm.

2. The substrate with transparent conductive film according to claim 1, wherein the transparent conductive film is amorphous.

3. The substrate with transparent conductive film according to claim 1, wherein the transparent conductive film is used for laser patterning.

4. The substrate with transparent conductive film according to claim 1, wherein the transparent conductive film has a film thickness of from 50 to 500 nm.

5. The substrate with transparent conductive film according to claim 1, wherein the transparent conductive film has a luminous transmittance of at least 70%.

6. The substrate with transparent conductive film according to claim 1, wherein the transparent conductive film has a specific resistance of at most 0.001 Ωcm.

7. The substrate with transparent conductive film according to claim 1, which has an undercoating film on the substrate side of the transparent conductive film.

8. The substrate with transparent conductive film according to claim 1, wherein the transparent conductive film is formed by sputtering at a substrate temperature of at most 250° C. during the film deposition.

9. A substrate with patterned transparent conductive film obtained by subjecting the substrate with transparent conductive film as defined in claim 1, to laser patterning.

10. The substrate with patterned transparent conductive film according to claim 9, which is heat-treated at a temperature of from 300 to 600° C.

11. A flat panel display employing the substrate with patterned transparent conductive film as defined in claim 9.

12. A patterning method for a substrate with transparent conductive film, which comprises patterning the substrate with transparent conductive film as defined in claim 1 by means of a laser.

13. The patterning method according to claim 12, wherein the laser energy of the laser is from 0.2 mJ to less than 1 mJ.

14. The patterning method according to claim 12, wherein the laser energy of the laser is from 0.2 mJ to 0.7 mJ.
